(19) United States
(12) Patent Application Publication
(10) Pub. No.: US 2008/0274627 A1
(43) Pub. Date: Nov. 6, 2008

(54) SILICON-CONTAINING FILM, FORMING MATERIAL, MAKING METHOD, AND SEMICONDUCTOR DEVICE

(75) Inventors: Yoshitaka HAMADA, Joetsu-shi (JP); Jun KAWAHARA, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: SHIN-ETSU CHEMICAL CO., LTD., Tokyo (JP); NEC CORPORATION, Tokyo (JP)

(21) Appl. No.: 12/113,618

(22) Filed: May 1, 2008

(30) Foreign Application Priority Data
May 1, 2007 (JP) 2007-120669

(51) Int. Cl. H01L 21/31; C07F 7/02; C07F 7/08; C07F 7/04; H01L 21/469

(52) U.S. Cl. 438/787; 556/465; 257/E21.24

(57) ABSTRACT

Using a cyclic siloxane compound having a vinyl group directly attached to a silicon atom and a relatively bulky substituent group containing a primary carbon vicinal to the silicon, a dielectric film, especially a low-k interlayer dielectric film can be formed by the plasma-enhanced CVD process.

### CROSS-REFERENCE TO RELATED APPLICATION

This non-provisional application claims priority under 35 U.S.C. §119(a) on Patent Application No. 2007-120669 filed in Japan on May 1, 2007, the entire contents of which are hereby incorporated by reference.

### TECHNICAL FIELD

This invention relates to a silicon-containing film-forming material which is useful as a low dielectric constant interlayer insulating material for use in the multi-level interconnect technology associated with logic ULSI, and which contains a cyclic siloxane compound suited for plasma-enhanced CVD, especially plasma polymerization. It also relates to a silicon-containing film, a method for preparing the film, and a semiconductor device using the film. The dielectric constant is often represented by “k” throughout the specification.

### BACKGROUND ART

In the integrated circuit field of the electronic industry, the manufacturing technology poses an increasing demand for higher integration and higher speed operation. For silicon ULSI, especially logic ULSI, the performance of interconnects becomes an outstanding task rather than the performance achievable by a size reduction of MOSFET. In order to solve the problem of wiring delay due to multi-level interconnect, it is required to reduce the wiring resistance and to reduce the capacitance between wirings and between layers.

Under the circumstances, it becomes essential to replace the aluminum wirings used in the majority of the current integrated circuits by copper wirings having a lower electric resistance and better migration resistance. A copper plating process is put to practical use.

A variety of low-k interlayer dielectric materials are known. The prior art used inorganic dielectric materials such as silicon dioxide (SiO₂), silicon nitride and phosphosilicate glass and organic dielectric materials such as polyimides. Spin-on-glass (SOG) materials were recently proposed for the purpose of providing a more uniform interlayer dielectric. For example, tetraethoxysilane monomer is subjected to hydrolysis or polycondensation to form SiO₂, which is used as a coating material referred to as inorganic SOG. Alternatively, an organic alkoxysilane monomer is subjected to polycondensation to form a polysiloxane, which is used as organic SOG.

The formation of dielectric layers is generally accomplished by two techniques, a coating technique of applying a dielectric polymer solution by spin coating, and a plasma-enhanced chemical vapor deposition technique of introducing a reactant(s) into a plasma for excitation and reaction and thus forming a film. The latter technique is abbreviated as plasma-enhanced CVD or PECVD.

With respect to the plasma-enhanced CVD technique, for example, U.S. Pat. No. 6,593,247 (or JP-A 2002-110670) describes a process of forming an oxidized trimethylsilane thin film from trimethylsilane and oxygen by the plasma-enhanced CVD technique. JP-A 11-288931 describes a process of forming an oxidized alkylsilane thin film from an alkoxysilane having a normal alkyl, alkenyl or aryl such as methyl, ethyl, n-propyl, vinyl or phenyl by the plasma-enhanced CVD technique. Although these dielectric films formed of prior art plasma CVD materials provide good adhesion to barrier metals and copper wiring materials, some suffer from a problem of film uniformity and some have an insufficient deposition rate and/or dielectric constant.

On the other hand, the coating technique provides good film uniformity, but is economically disadvantageous because it involves three steps of coating, solvent removal and heat treatment, that is, requires more steps than the CVD technique. Problems often arise with respect to the adhesion of a coating to barrier metals and copper serving as the wiring material and the uniform application of a coating liquid to a micropatterned substrate structure.

In connection with the coating material, a technique of rendering the material porous was proposed in order to develop a ultra low-k material having a dielectric constant of 2.5 or less, and preferably 2.0 or less. One technique for preparing porous material is by dispersing fine particulates of pyrolyzable organic component in an organic or inorganic material matrix and heat treating the matrix to be porous. Another technique is by evaporating silicon and oxygen into a gas to form SiO₂ ultra-fine particulates and depositing the particulates to form a thin film of SiO₂ ultra-fine particulates.

Although these porosity-providing techniques are effective in reducing the dielectric constant, there remain some problems that mechanical strength is reduced, chemical mechanical polishing (CMP) thus becomes difficult, and moisture absorption can incur an increase of dielectric constant and wiring corrosion.

Therefore, the market is still seeking for a well-balanced material capable of meeting all the requirements including a low dielectric constant, sufficient mechanical strength, adhesion to barrier metals, copper diffusion prevention, plasma ashing resistance, and moisture resistance. One method proposed to meet these requirements in an acceptable balance is by modifying an organic silane material so as to increase the proportion of carbon from organic substituent groups relative to the silane, thus yielding a material having intermediate characteristics between organic and inorganic polymers.

For instance, JP-A 2000-302791 describes that an interlayer dielectric having a dielectric constant of 2.4 or less is obtained using a coating solution resulting from hydrolytic polycondensation of a silicon compound having an adamantyl group in the co-presence of an acidic aqueous solution by the sol-gel technique.

Also proposed was a new method of forming a Si-containing film by plasma-enhanced CVD using a silane compound having a radical polymerizable organic group on a side chain, wherein the polymerizable organic group is polymerized under the CVD conditions to form a Si-containing film (see Shun-Gyu Park et al., J. Vac. Sci. Technol. A24(2), 191 (2006)). Subsequent to this proposal, the latest method of forming a low-k dielectric film by CVD was proposed in Proceedings of IEEE International Interconnect Technology Conference, 2004, pp. 225-227. A low-k dielectric film is formed by plasma-enhanced CVD of a cyclic siloxane having a vinyl group on a side chain.

### DISCLOSURE OF THE INVENTION

An object of the invention is to provide a novel silicon-containing film-forming material, specifically a silicon-containing film-forming material comprising a cyclic siloxane compound which is compliant with a plasma-enhanced CVD apparatus and useful in forming a low-k dielectric film; a Si-containing film using the material; a method for preparing the film; and a semiconductor device using the Si-containing film as a dielectric film.

The inventor has found that a cyclic siloxane compound having a vinyl group directly attached to a silicon atom is suitable as a material for forming a dielectric film, especially a low-k interlayer dielectric film for semiconductor devices, and that when the siloxane compound has a substituent group on silicon other than the vinyl group, and the substituent group contains a primary carbon vicinal to the silicon and has a certain bulkiness, then a silica film having a low k can be formed by the plasma-enhanced CVD process because the elimination of the alkyl group during the process is restrained.

In a first aspect, the invention provides a silicon-containing film-forming material comprising a vinyl-containing cyclic siloxane compound having the general formula (1).

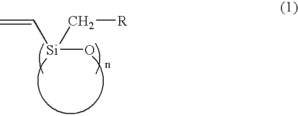

Herein R is a straight or branched alkyl group of 1 to 4 carbon atoms and n is an integer of 3 to 5. When the material is processed by plasma-enhanced CVD, a silica film having a low k can be formed because the elimination of the alkyl group is restrained.

In one preferred embodiment, R in formula (1) is an alkyl group selected from methyl, ethyl, n-propyl and is isopropyl. Typically, the compound having formula (1) is 1,3,5,7-tetraisobutyl-1,3,5,7-tetravinylcyclotetrasiloxane or 1,3,5,7-tetrapropyl-1,3,5,7-tetravinylcyclotetrasiloxane.

The Si-containing film-forming material contains silicon, carbon, oxygen, hydrogen, and impurities. Preferably, each of the impurities is present at a level of less than 10 ppb of impurity atoms, and the material has a water content of less than 50 ppm. Such a high purity insures that the material is used to manufacture semiconductor devices in high percent yields.

In a second aspect, the invention provides a method for forming a silicon-containing film comprising using the silicon-containing film-forming material defined above as a starting material.

Preferably the method may further comprise chemical vapor deposition of the material. The chemical vapor deposition technique is typically a plasma-enhanced chemical vapor deposition (PECVD) technique. Preferably the PECVD technique utilizes a plasma excitation power equal to or less than 500 watts. Then the elimination of the alkyl group is more effectively restrained during the deposition, and a lower k is achievable.

In a preferred embodiment, the PECVD technique causes polymerization of the compound having formula (1) via the vinyl group with the alkyl group left intact. A film is deposited at a low level of energy so that the alkyl group is left within the film. This is advantageous in forming a low k dielectric film.

Typically the PECVD technique utilizes a rare gas as the carrier gas. The preferred rare gas is helium.

In a third aspect, the invention provides a silicon-containing film obtained by the method defined above. Typically the silicon-containing film comprises a cyclic siloxane structure having the general formula (2).

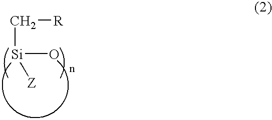

Herein R is a straight or branched alkyl group of 1 to 4 carbon atoms, Z is a crosslinked structure group derived from a vinyl group, and n is an integer of 3 to 5.

In a fourth aspect, the invention provides a semiconductor device comprising the silicon-containing film defined above as a dielectric film. Using the Si-containing film having a low k, a semiconductor device with high performance can be established.

In a fifth aspect, the invention provides a method for preparing a cyclic siloxane compound having the general formula (1) defined above, comprising the step of reacting a compound having the general formula (3) with water in the presence of an acid or base.

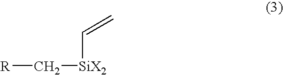

Herein R is a straight or branched alkyl group of 1 to 4 carbon atoms and X is a hydrolyzable group capable of reaction with water to yield a hydroxyl group. Using the compound of formula (3), a cyclic siloxane of formula (1) can be effectively prepared.

### BENEFITS OF THE INVENTION

According to the invention, a dielectric film, especially a low-k interlayer dielectric film for semiconductor devices is formed by using as a starting material a cyclic siloxane compound having a vinyl group directly attached to a silicon atom and a substituent group on the silicon atom other than the vinyl group, the substituent group containing a primary carbon vicinal to the silicon, and effecting CVD, especially plasma-enhanced CVD. Since the elimination of the alkyl group during the plasma-enhanced CVD process is restrained, the resulting silica film can have a low k.

Since the film deposition process does not use any organic solvent, there are obtained advantages including efficient utilization of the organic monomer and a reduced environmental load. The utilization of this film deposition process for the deposition of multi-level interconnect dielectric film enables a semiconductor integrated circuit with a minimized wiring signal delay.

### BRIEF DESCRIPTION OF THE DRAWING

FIG. 1 schematically illustrates a film deposition system used in Examples.

### DESCRIPTION OF THE PREFERRED EMBODIMENT

The terms “a” and “an” herein do not denote a limitation of quantity, but rather denote the presence of at least one of the referenced item. As used herein, the term “ppm” is parts by weight per million parts by weight, and “ppb” is parts by weight per billion parts by weight.

According to the invention, a material comprising a vinyl-containing cyclic siloxane compound having the general formula (1) is used in forming a Si-containing film.

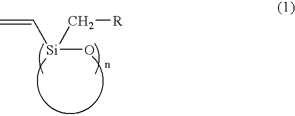

Herein R is a straight or branched alkyl group of 1 to 4 carbon atoms and n is an integer of 3 to 5.

When applied to the Si-containing film forming method of the invention, the compound of formula (1) is preferably fed in a vapor phase to the film deposition zone. Thus the preferred cyclic siloxane compound has a relatively low molecular weight so that it has a vapor pressure below the decomposition temperature of the reactant. In this sense, the cyclic structure should preferably be equal to or less than a 10-membered ring, and more preferably equal to or less than a 8-membered ring. The organic group R on the Si atom other than the vinyl group should have 4 or less carbon atoms.

From the standpoint of a low dielectric constant (k), the substituent group should preferably be bulky enough to provide a space volume. The alkyl group represented by R in formula (1) is preferably selected to be larger, with an alkyl of at least two carbon atoms, especially at least three carbon atoms being advantageous in achieving lower values of k.

Illustrative, non-limiting examples of the cyclic siloxane include

cyclotrisiloxanes such as
1,3,5-trivinyl-1,3,5-triethylcyclotrisiloxane,
1,3,5-trivinyl-1,3,5-tri-n-propylcyclotrisiloxane,
1,3,5-trivinyl-1,3,5-tri-n-butylcyclotrisiloxane,
1,3,5-trivinyl-1,3,5-tri-1-butylcyclotrisiloxane,
1,3,5-trivinyl-1,3,5-tri-n-pentylcyclotrisiloxane,
1,3,5-trivinyl-1,3,5-tri-1-pentylcyclotrisiloxane, and
1,3,5-trivinyl-1,3,5-tri-neo-pentylcyclotrisiloxane;

cyclotetrasiloxanes such as
1,3,5,7-tetravinyl-1,3,5,7-tetraethylcyclotetrasiloxane,
1,3,5,7-tetravinyl-1,3,5,7-tetra-n-propylcyclotetrasiloxane,
1,3,5,7-tetravinyl-1,3,5,7-tetra-n-butylcyclotetrasiloxane,
1,3,5,7-tetravinyl-1,3,5,7-tetra-i-butylcyclotetrasiloxane,
1,3,5,7-tetravinyl-1,3,5,7-tetra-n-pentylcyclotetrasiloxane,
1,3,5,7-tetravinyl-1,3,5,7-tetra-i-pentylcyclotetrasiloxane,
and 1,3,5,7-tetravinyl-1,3,5,7-tetra-neo-pentylcyclotetrasiloxane; and

cyclopentasiloxanes such as
1,3,5,7,9-pentavinyl-1,3,5,7,9-pentaethylcyclopentasiloxane,
1,3,5,7,9-pentavinyl-1,3,5,7,9-penta-n-propylcyclopentasiloxane,
1,3,5,7,9-pentavinyl-1,3,5,7,9-penta-n-butylcyclopentasiloxane, and
1,3,5,7,9-pentavinyl-1,3,5,7,9-penta-i-butylcyclopentasiloxane.
Inter alia, 1,3,5,7-tetraisobutyl-1,3,5,7-tetravinylcyclotetrasiloxane and 1,3,5,7-tetrapropyl-1,3,5,7-tetravinylcyclotetrasiloxane are most preferred.

The invention is characterized in that the substituent groups on Si are a vinyl group and a primary alkyl group having a certain bulkiness. We believe that this feature ensures formation of a low-k film for the following reason. In the prior art technology of forming a low-k film from a cyclic siloxane by plasma-enhanced CVD, it was uncertain how to design the function of substituent groups on a silicon atom. We worked under the hypothesis that a film serving as an effective low-k film would be obtained by assigning to a vinyl group a polymerization function to form a film and allowing another substituent group to survive in the plasma-enhanced CVD film so as to insure a low-k. We then attempted to use a vinyl group as one of the substituent groups on Si and a bulky alkyl group as the other substituent group, provided that other physical properties, for example, an appropriate boiling point are met.

On the other hand, if a focus is directed to only the bulkiness of alkyl group, a group having a bond site of branched structure such as iso-propyl or tert-butyl may be a candidate. When the above idea that the alkyl group is positively left as such within the plasma-enhanced CVD film is taken into account, there is a possibility that a choice of a primary alkyl group providing a more stable bond between silicon and alkyl is advantageous.

It is anticipated from the common chemical knowledge that the primary alkyl group selected as the substituent group to form a more stable bond with a silicon atom is more stable under the CVD conditions than the secondary alkyl group. When the reaction energy of the following formula (4) was determined by computation of MP2/6-31G(d,p)//HF/6-31G(d) level using Gaussian 98, it was supported that there is a definite difference between n-propyl and iso-propyl as seen from Table 1.

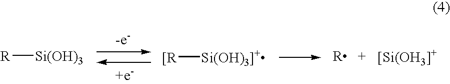

TABLE 1

| R | Reaction energy (kcal/mol) |
|---|---|
| Methyl | −20.2 |
| Ethyl | −28.8 |
| n-Propyl | −31.4 |
| Iso-propyl | −35.2 |

Namely, it is believed that when the cyclic siloxane compound contemplated herein is under very weak plasma conditions, any reactivity other than the polymerization reaction of vinyl groups can be maintained low, and a selectivity of polymerization reaction under the CVD conditions can be readily enhanced without incurring ring-opening reaction of siloxane and elimination reaction of alkyl groups. It is then believed that the film obtained by plasma-enhanced CVD using the cyclic siloxane compound of the invention comprises a cyclic siloxane structure having the general formula (2):

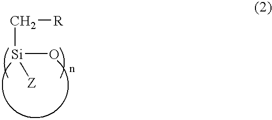

wherein R is a straight or branched alkyl group of 1 to 4 carbon atoms, Z is a crosslinked structure group derived from a vinyl group, and n is an integer of 3 to 5. This structure ensures a low dielectric constant.

The crosslinked structure group derived from a vinyl group, represented by Z, is a group resulting from polymerization and crosslinking of vinyl groups because vinyl groups on the cyclic siloxane compound of formula (1) are polymerized together.

The Si-containing film-forming material of the invention contains a vinyl-containing cyclic siloxane compound having formula (1). Specifically, the material contains silicon, carbon, oxygen, hydrogen, and impurities. In order that the material be used as a semiconductor material, each of the impurities is preferably present at a level of less than 10 ppb of impurity atoms, and the material has a water content of less than 50 ppm. In one embodiment, the Si-containing film-forming material consists of a vinyl-containing cyclic siloxane compound having formula (1). In another embodiment, the material may contain additional compounds, for example, alkenyl-substituted silane compounds, and SiH₄, CH₃SiH₄, (CH₃)₂Si(OCH₃)₂, Si(OC₂H₅)₄, (CH₃)₃SiH, (CH₃)₄Si and similar silanes which are commonly used in Si-containing film formation.

It is not critical how to prepare the cyclic siloxane of formula (1). In one embodiment, the cyclic siloxane compound having formula (1) is prepared by hydrolytic condensation of a hydrolyzable silane compound having a vinyl group and a primary alkyl group both substituted on a silicon atom, represented by the general formula (3), in the presence of an acid or base catalyst.

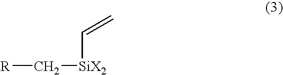

Herein R is a straight or branched alkyl group of 1 to 4 carbon atoms and X is a hydrolyzable group capable of reaction with water to yield a hydroxyl group.

Examples of the alkyl group represented by R include methyl, ethyl, n-propyl and iso-propyl. A more number of carbon atoms is preferred to gain a low dielectric constant in an advantageous manner, with alkyl groups of two or more carbon atoms, and especially three or more carbon atoms being desired.

Examples of the hydrolyzable group represented by X include alkoxy groups, typically alkoxy groups of 1 to 4 carbon atoms, acyloxy groups, typically acetyl, and halogens, typically chlorine.

Illustrative examples of the silane of formula (3) include vinylethyldimethoxysilane, vinylethyldiethoxysilane, vinylethyldiacetoxysilane, vinylethyldichlorosilane, vinylpropyldimethoxysilane, vinylpropyldiethoxysilane, vinylpropyldiacetoxysilane, vinylpropyldichlorosilane, vinyl-n-butyldimethoxysilane, vinyl-n-butyldiethoxysilane, vinyl-n-butyldiacetoxysilane, vinyl-n-butyldichlorosilane, vinyl-iso-butyldimethoxysilane, vinyl-iso-butyldiethoxysilane, vinyl-iso-butyldiacetoxysilane, and vinyl-iso-butyldichlorosilane.

Suitable acids used as the hydrolytic condensation catalyst include mineral acids such as hydrochloric acid, nitric acid and sulfuric acid, and organic acids such as toluenesulfonic acid. Suitable basic catalysts include sodium hydroxide, potassium hydroxide, sodium methoxide, potassium methoxide, sodium ethoxide, potassium ethoxide, sodium tert-butoxide, and potassium tert-butoxide.

Any of well-known reaction solvents may be used during the hydrolytic condensation. Illustrative non-limiting examples of suitable solvents include saturated hydrocarbons such as n-pentane, i-pentane, n-hexane, cyclohexane, n-heptane, and n-decane; unsaturated hydrocarbons such as toluene, xylene, and decene-1; ethers such as diethyl ether, dipropyl ether, tert-butyl methyl ether, dibutyl ether, cyclopentyl methyl ether, and tetrahydrofuran; and alcohols such as methanol, ethanol, isopropanol, n-butanol, tert-butanol, and 2-ethylhexanol. Mixtures of such solvents are also useful. Particularly when ethers or alcohols are used, cyclic siloxane compounds of formula (1) having a specific molecular weight can be prepared in high yields.

The reaction to produce a cyclic siloxane compound of formula (1) is generally carried out at 0 to 150° C. under atmospheric pressure though the reaction conditions are not particularly limited.

For the purification of the resulting cyclic siloxane compound of formula (1), the reaction product is purified and isolated typically by vacuum distillation although it is sometimes difficult to isolate and purify cyclics having different numbers of ring members. If it is desired to obtain a product having a matched number of ring members, matching to a more stable number of ring members is achievable by heating under reflux in an organic solvent in the presence of alkali hydroxide. In some cases, a mixture of cyclics having different numbers of ring members may be used as the film-forming material. After the foregoing treatment is optionally carried out, vacuum distillation can be carried out to reduce the impurity metal content below 10 ppb and the water content below 50 ppm. Now that the impurity content is reduced below the specific level, the material is best suited as a material for forming a low-k dielectric film by the CVD process.

If the finally obtained cyclic siloxane compound of formula (1) has a high water content and high contents of impurities other than silicon, carbon, oxygen and hydrogen, especially high contents of metal impurities, it is unsuitable as the dielectric film-forming material.

If the compound contains by-products having a silanol structure, the by-products can be removed by treating the product with sodium or potassium hydride for converting the hydroxyl group of silanol to the sodium or potassium salt, which precipitates, followed by distillation.

During the preparation of the cyclic siloxane compound of formula (1), other conditions may be compliant with the standard method employed in the relevant organic synthesis or organometallic synthesis field. Specifically, the atmosphere used is a nitrogen or argon atmosphere which has been dried and deoxygenated, and the solvent used and the column packing for purification should preferably be pre-dried. Removal of metal residues and impurities such as particles is also preferable.

According to the invention, a Si-containing film can be prepared using a Si-containing film-forming material comprising the siloxane compound of formula (1). In a preferred embodiment, a Si-containing film is prepared by the CVD process, and especially the plasma-enhanced CVD process. This PECVD process is desirable to deposit in a lower energy region than the energy region commonly employed in ordinary PECVD. When a parallel plate type PECVD system is loaded with a 300-mm wafer, for example, it is preferred for reducing the dielectric constant that the RF power applied across the electrodes (also referred to as plasma excitation power) is preferably equal to or less than 500 watts, more preferably equal to or less than 300 watts, and even more preferably equal to or less than 200 watts. This is because reaction at a lower energy level reflects more of a difference of bond strength in the reactant, and a selectivity of polymerization reaction of the most active vinyl group is enhanced.

According to the invention, film formation is carried out under low energy plasma-enhanced CVD conditions, so that decomposition reactions other than the polymerization reaction of vinyl groups are restrained. Then polymerization, deposition and film formation is accomplished without substantially disrupting the structure the monomer originally possesses. Then the above object is achievable using a compound having a Si—C bond with a higher energy level like the compound of formula (1).

In fact, films were formed by plasma-enhanced CVD using cyclic siloxane compounds of formulae (5) to (7) as the starting reactant.

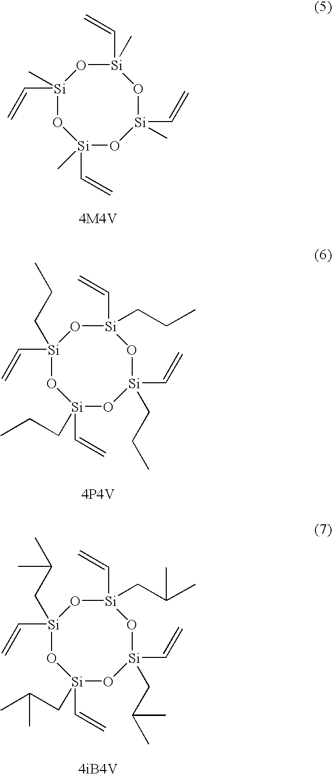

Films formed from 1,3,5,7-tetrapropyl-1,3,5,7-tetravinylcyclotetrasiloxane (4P4V) and 1,3,5,7-tetraisobutyl-1,3,5,7-tetravinylcyclotetrasiloxane (4iB4V) were measured for a dielectric constant (k). A film with k=2.7 was obtained when deposited at an applied power of 500 W. As the power was reduced, the k value was decreased. A film with k=2.4 was obtained when deposited at a power of 100 W. Understandably this is because at a lower energy level, decomposition of a Si—C bond is more effectively restrained and polymerization/deposition reaction by polymerization of vinyl groups becomes predominant.

This is not the case with 1,3,5,7-tetramethyl-1,3,5,7-tetravinylcyclotetrasiloxane (4M4V). A film formed from 4M4V at an applied power of 500 W had a k value of 2.74 which is slightly higher than that of 4iB4V. However, even when the applied power was reduced to 150 W, the film had a k value of 2.52, failing to reach a k value of less than 2.5 as in the case of 4iB4V and 4P4V. It is understood that methyl fails to exert the effect of achieving a low-k value because the space volume of methyl is smaller than that of propyl or iso-butyl.

In the practice of plasma-enhanced CVD, the monomer or compound of formula (1) should preferably be used in vapor form along with a carrier gas, which is preferably a rare gas, especially helium gas. Other conditions of plasma-enhanced CVD may accord with well-known standard conditions. With the above-mentioned process, a Si-containing film having a cyclic siloxane structure of formula (2) is obtainable.

### EXAMPLE

Examples of the invention are given below by way of illustration and not by way of limitation.

### Synthesis Example 1

### Synthesis of Propylvinyldimethoxysilane

A Grignard reagent which had been prepared from n-propyl chloride and metallic magnesium in tetrahydrofuran (THF) solvent was added dropwise to a THF solution of vinyltrimethoxysilane. Following the dropwise addition, the reaction mixture was ripened under reflux for 2 hours. Hexane was added to the reaction solution, from which the salt of Grignard reagent was removed by filtration. The end compound was collected by vacuum distillation.

### Synthesis Example 2

### Synthesis of iso-butylvinyldimethoxysilane

The end compound was obtained by the same synthesis procedure as in Synthesis Example 1 aside from using iso-butyl chloride instead of n-propyl chloride.

### Synthesis Example 3

### Synthesis of 4P4V

To a THF solution of 50 g propylvinyldimethoxysilane, obtained in Synthesis Example 1, 10 g of a 10% NaOH aqueous solution was added dropwise. The reaction mixture was ripened under reflux for 4 hours. The reaction solution was combined with ethyl acetate, and washed and neutralized with aqueous hydrochloric acid. The end compound was collected by vacuum distillation. Boiling point 75° C./8.5 kPa, yield 80%.

### Synthesis Example 4

### Synthesis of 4iB4V

The end compound was obtained by the same synthesis procedure as in Synthesis Example 3 aside from using iso-butylvinyldimethoxysilane. Boiling point 118° C./260 Pa, yield 75%.

### Example 1

### Deposition Using 4P4V

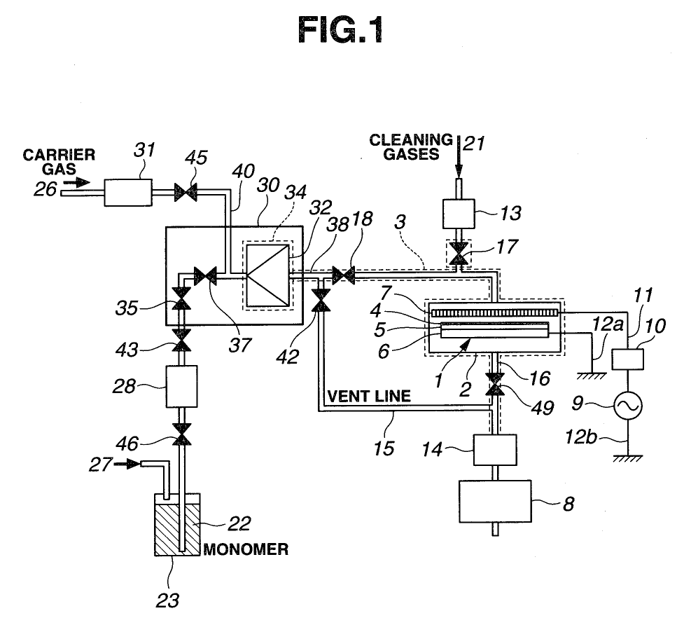

Referring to the deposition system shown in FIG. 1, the process of depositing a film from a gas mixture in a plasma-enhanced CVD apparatus is described wherein 4P4V (tetrapropyltetravinylcyclotetrasiloxane) of formula (6) is used as the monomer, vaporized, and carried by helium (He) as the carrier gas.

In the deposition system, when a controllable vaporizer 30 is in the initial state, with valves 18 and 47 kept open and other valves kept closed, a vacuum pump 8 is operated to evacuate a reaction chamber 1 with a heater 2, an exhaust conduit 16, a waste liquid conduit 15, a vaporizing chamber 32 with a heater 34, and a vaporized reactant feed conduit 38. The vaporizing temperature is desirably a sufficient temperature to provide a necessary supply of a monomer 22, but should be a temperature which does not incur alteration (like decomposition or polymerization) to monomer 22 itself in a conduit section for feeding monomer 22 (to be vaporized) to vaporizing chamber 32 or cause clogging of the conduit as a result of such alteration. Also conduit members to be heated by a heater 3 including vaporized reactant feed conduit 38 should withstand the heating temperature, or conditions should be selected such that the heating temperature can be set within the heat resistant temperature range of the conduit members used. While the temperature of a conduit being heated is monitored by thermocouples located at different positions on the conduit, the output of the conduit heater is controlled so as to maintain the preset temperature constantly.

With a valve 45 kept open, carrier gas (He) 26 is fed from a carrier gas feed conduit 40 to controllable vaporizer 30 through a gas flow rate controller 31, passed into reaction chamber 1 through vaporized reactant feed conduit 38, and exhausted out of the system via exhaust conduit 16 by vacuum pump 14. In the vaporizing step wherein monomer 22 used was 4P4V, the vaporizing temperature was set at 110° C. The flow rate of 4P4V was 0.3 g/min and the flow rate of He carrier gas was 500 sccm. At this time, reaction chamber 1 had an internal pressure of 5 Torr, and vaporizing chamber 32 had a total pressure of 5.7 Torr. By a substrate heating section 6 disposed in reaction chamber 1, a silicon substrate (or semiconductor substrate) 5 having a semiconductor integrated circuit formed thereon was heated at 350° C. When the reactant within the scope of the invention is used, it is appropriate to select a substrate heating temperature in the range of 200 to 450° C. during deposition.

While a valve 37 in controllable vaporizer 30 is kept open and valves 43 and 46 kept open, monomer 22 (4P4V) is displaced from a monomer tank 23 by pressure feed gas 27, and fed to controllable vaporizer 30 through a liquid flow meter 28. Using the measured value of flow meter 28, the degree of opening of a vaporization rate controlling valve 35 in controllable vaporizer 30 is controlled so that the desired flow rate is established. Additionally, with a valve 37 in controllable vaporizer 30 turned open, monomer 22 in admixture with He carrier gas 26 is vaporized in vaporizing chamber 32. Thereafter, the gas mixture is delivered to reaction chamber 1 through vaporized reactant feed conduit 8. Through a shower head 7 in reaction chamber 1, the gas mixture is dispersed and sprayed to the surface of substrate 5. An RF power having a frequency of 13.56 MHz is applied across shower head 7 relative to the surface of substrate heating section 6 which is grounded, whereby a plasma of He as the carrier gas is created below shower head 7. At this point, it is crucial that the RF power be limited to a plasma energy sufficient to activate only an unsaturated bond within the reactant molecule serving as a reaction site. Also illustrated are an RF power source 9, a matching box 10, an RF cable 11, and ground lines 12a, 12b. While the reactant gas mixture is sprayed onto semiconductor substrate 5 through the He plasma, the reactant in the mixture is activated. The activated reactant undergoes polymerization reaction on the substrate surface heated at 350° C., forming a polymerized film 4 composed of skeleton units derived from tetrapropyltetravinylcyclotetrasiloxane (4P4V). Then the carrier gas containing unreacted reactant reaches exhaust conduit 16. The majority of 4P4V contained therein is liquefied again and collected in a cooling trap 14 disposed upstream of vacuum pump 8 so that it does not enter vacuum pump 8. Film deposition is continued by feeding the reactant until the total supply reaches the predetermined amount. Thereafter, the supplies are interrupted, and semiconductor substrate 5 is unloaded from reaction chamber 1. The dielectric constant (k) of the resulting film is measured. At a power of 350 W, a film with k=2.6 was obtained. As the RF power was reduced, the value of k became smaller. At a power of 150 W, a film with k=2.4 was obtained.

In this Example, both carrier gas 26 and purge/pressure feed gas 27 are helium (He). A cleaning gas 21 is fed to reaction chamber 1 through a gas flow rate controller 13 and a valve 17 for cleaning reaction chamber 1. The cleaning gas 21 is a gas mixture of a fluorocarbon gas such as CF₄ or C₂F₆ and oxygen or ozone. Also useful is a gas mixture of NF₃ or SF₆ and oxygen or ozone.

### Example 2

### Deposition Using 4iB4V

Referring to the deposition system shown in FIG. 1, the process of depositing a film from a gas mixture in a plasma-enhanced CVD apparatus is described wherein 4iB4V (tetraisobutyltetravinylcyclotetrasiloxane) of formula (7) is used as monomer 22, vaporized, and carried by helium (He) as carrier gas 26.

During film deposition, the initial state of the system and various set temperatures are the same as in Example 1. In the vaporizing step wherein monomer 22 used was 4iB4V, the vaporizing temperature was set at 120° C. The flow rate of 4iB4V was 0.3 g/min and the flow rate of He carrier gas was 500 sccm. At this time, reaction chamber 1 had an internal pressure of 3.5 Torr, and vaporizing chamber 32 had a total pressure of 4.2 Torr. By substrate heating section 6 in reaction chamber 1, silicon substrate (or semiconductor substrate) 5 having a semiconductor integrated circuit formed thereon was heated at 350° C.

The procedure of feeding 4iB4B and depositing a polymerized film 4 was also the same as in Example 1. The dielectric constant (k) of the resulting film was measured. At an RF power of 75 W, a film with k=2.4 was obtained. When the reaction chamber pressure was 4 Torr, a film with k=2.6 was obtained at an RF power of 300 W.

Japanese Patent Application No. 2007-120669 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A silicon-containing film-forming material comprising a vinyl-containing cyclic siloxane compound having the general formula (1): 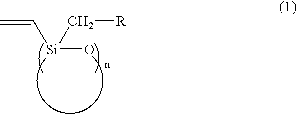
wherein R is a straight or branched alkyl group of 1 to 4 carbon atoms and n is an integer of 3 to 5.

2. The material of claim 1 wherein in formula (1), R is an alkyl group selected from methyl, ethyl, n-propyl and isopropyl.

3. The material of claim 1 wherein the compound having formula (1) is 1,3,5,7-tetraisobutyl-1,3,5,7-tetravinylcyclotetrasiloxane or 1,3,5,7-tetrapropyl-1,3,5,7-tetravinylcyclotetrasiloxane.

4. The material of claim 1 which contains silicon, carbon, oxygen, hydrogen, and impurities, each of the impurities being present at a level of less than 10 ppb of impurity atoms, and the material has a water content of less than 50 ppm.

5. A method for forming a silicon-containing film comprising using the silicon-containing film-forming material of claim 1 as a starting material.

6. The method of claim 5 further comprising chemical vapor deposition of the material.

7. The method of claim 6 wherein the chemical vapor deposition technique is a plasma-enhanced chemical vapor deposition technique.

8. The method of claim 7 wherein the plasma-enhanced chemical vapor deposition technique utilizes a plasma excitation power equal to or less than 500 watts.

9. The method of claim 7 wherein the plasma-enhanced chemical vapor deposition technique causes polymerization of the compound having formula (1) via the vinyl group with the alkyl group left.

10. The method of claim 7 wherein the plasma-enhanced chemical vapor deposition technique utilizes a rare gas as the carrier gas.

11. The method of claim 10 wherein the rare gas is helium.

12. A silicon-containing film produced by the method of claim 5.

13. The silicon-containing film of claim 12 comprising a cyclic siloxane structure having the general formula (2): 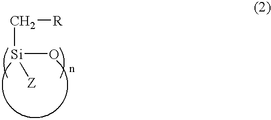
wherein R is a straight or branched alkyl group of 1 to 4 carbon atoms, Z is a crosslinked structure group derived from a vinyl group, and n is an integer of 3 to 5.

14. A semiconductor device comprising the silicon-containing film of claim 12 as a dielectric film.

15. A method for preparing a cyclic siloxane compound having the general formula (1) as set forth in claim 1, comprising the step of reacting a compound having the general formula (3) with water in the presence of an acid or base, 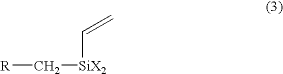
wherein R is a straight or branched alkyl group of 1 to 4 carbon atoms and X is a hydrolyzable group capable of reaction with water to yield a hydroxyl group.
